(19) United States
(12) Patent Application Publication
(10) Pub. No.: US 2013/0126915 A1
(43) Pub. Date: May 23, 2013

(54) FLEXIBLE ACTIVE DEVICE ARRAY SUBSTRATE AND ORGANIC ELECTROLUMINESCENT DEVICE HAVING THE SAME

(71) Applicants: Chi-Shun Chan, Taoyuan County (TW); Shih-Hsing Hung, Hsinchu County (TW); Chih-Jen Hu, Hsinchu City (TW)

(72) Inventors: Chi-Shun Chan, Taoyuan County (TW); Shih-Hsing Hung, Hsinchu County (TW); Chih-Jen Hu, Hsinchu City (TW)

(73) Assignee: AU OPTRONICS CORPORATION, Hsinchu (TW)

(21) Appl. No.: 13/439,880

(22) Filed: Apr. 5, 2012

(30) Foreign Application Priority Data
Nov. 17, 2011 (TW) 100142005

(51) Int. Cl. H01L 27/15; H01L 27/10

(52) U.S. Cl. 257/88; 257/499; 257/40; 257/E27.07; 257/E27.121

(57) ABSTRACT

A flexible active device array substrate including a flexible substrate, an active device array layer, a barrier layer, and a plurality of pixel electrodes is provided. The active device array layer is disposed on the flexible substrate. The barrier layer covers the active device array layer. The barrier layer includes a plurality of organic material layers and a plurality of inorganic material layers. The organic material layers and the inorganic material layers are alternately stacked on the active device array layer. The pixel electrodes are disposed on the barrier layer, and each of the pixel electrodes is electrically connected to the active device array layer.

### CROSS-REFERENCE TO RELATED APPLICATION

This application claims the priority benefit of Taiwan application serial no. 100142005, filed on Nov. 17, 2011. The entirety of the above-mentioned patent application is hereby incorporated by reference herein and made a part of this specification.

### BACKGROUND OF THE INVENTION

1. Field of the Invention

The application relates to an active device array substrate, and in particular to a flexible active device array substrate.

2. Description of Related Art

Organic electroluminescent devices have been considered a dominant flat panel display in the future because of their desirable qualities of compactness, self-luminescence, low power consumption, no need of backlight source, no viewing angle limitation, and high response speed. To be able to broadly apply the organic electroluminescent device, a flexible organic electroluminescent device has been developed. Whether a display is flexible is determined by a material of a substrate in the display. When the display has a rigid substrate, the display is not characterized by flexibility. On the contrary, when the display has a flexible substrate (e.g., a plastic substrate), the display features flexibility.

In general, a passivation layer of a thin film transistor (TFT) is frequently made of an inorganic material (e.g., silicon nitride). Said technique is rather mature and has been extensively applied in a variety of displays. Nonetheless, in the process of fabricating a flexible organic electroluminescent device, the unfavorable flexibility of the inorganic material may cause cracks in the passivation layer after the TFT is bent. Thereby, water vapor (humidity) penetrates the passivation layer through the cracks and thus affects the electrical properties of the TFT.

If the passivation layer is made of an organic material, the TFT may be characterized by favorable flexibility. However, water resistance of the organic material is not as good as that of the inorganic material, and accordingly water vapor (humidity) is apt to penetrate the TFT and thereby affects the electrical properties of the TFT. In comparison with the common rigid substrate (e.g., a glass substrate), when a flexible substrate applied is made of plastic, water vapor (humidity) is prone to penetrate the TFT through a direction of the plastic substrate, thus posing an impact on the electrical properties of the TFT. As a result, how to improve the reliability of a flexible active device array substrate is one of the issues to be resolved imminently.

### SUMMARY OF THE INVENTION

The application is directed to a flexible active device array substrate and an organic electroluminescent device with favorable reliability.

In the application, a flexible active device array substrate including a flexible substrate, an active device array layer, a barrier layer, and a plurality of pixel electrodes is provided. The active device array layer is disposed on the flexible substrate. The barrier layer covers the active device array layer. The barrier layer includes a plurality of organic material layers and a plurality of inorganic material layers. The organic material layers and the inorganic material layers are alternately stacked on the active device array layer. The pixel electrodes are disposed on the barrier layer, and each of the pixel electrodes is electrically connected to the active device array layer.

In the application, an organic electroluminescent device including the flexible active device array substrate, an organic electroluminescent layer, and an electrode layer is provided. The organic electroluminescent layer is disposed on the flexible active device array substrate. The electrode layer is disposed on the organic electroluminescent layer. Besides, the electrode layer is electrically insulated from the pixel electrodes.

According to an embodiment of the invention, a water vapor transmission rate (WVTR) of the barrier layer is substantially equal to or less than 10⁻² g/m²·Day.

According to an embodiment of the invention, the bottommost organic material layer in the flexible active device array substrate is in contact with the active device array layer.

According to an embodiment of the invention, the bottommost inorganic material layer in the flexible active device array substrate is in contact with the active device array layer.

According to an embodiment of the invention, the flexible active device array substrate further includes an inner barrier layer disposed between the flexible substrate and the active device array layer.

According to an embodiment of the invention, the flexible active device array substrate further includes a first outer barrier layer. The first outer barrier layer is disposed on an outer surface of the flexible substrate, and the inner barrier layer and the first outer barrier layer are respectively located at two opposite sides of the flexible substrate.

According to an embodiment of the invention, the flexible active device array substrate further includes a second outer barrier layer disposed on an outer surface of the first outer barrier layer, and the first outer barrier layer is located between the second outer barrier layer and the flexible substrate.

According to an embodiment of the invention, the flexible active device array substrate further includes a second outer barrier layer and a de-bonding layer. The second outer barrier layer is disposed on an outer surface of the first outer barrier layer, and the first outer barrier layer is located between the second outer barrier layer and the flexible substrate. The de-bonding layer is adhered between the first outer barrier layer and the second outer barrier layer.

According to an embodiment of the invention, the flexible active device array substrate further includes a de-bonding layer. The de-bonding layer is disposed on an outer surface of the first outer barrier layer.

Based on the above, the barrier layer that is stacked by the organic material layers and the inorganic material layers alternately is integrated into the fabrication of the flexible active device array substrate. Therefore, the flexible active device array substrate described in the embodiments of the invention has flexibility and low WVTR.

In order to make the aforementioned and other features and advantages of the invention more comprehensible, embodiments accompanying figures are described in detail below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1 is a schematic cross-sectional view illustrating a flexible active device array substrate according to a first embodiment of the invention.

FIG. 2 is a schematic cross-sectional view illustrating a flexible active device array substrate according to a second embodiment of the invention.

FIG. 3 is a schematic cross-sectional view illustrating a flexible active device array substrate according to a third embodiment of the invention.

FIG. 4 is a schematic cross-sectional view illustrating a flexible active device array substrate according to a fourth embodiment of the invention.

FIG. 5 is a schematic cross-sectional view illustrating a flexible active device array substrate according to a fifth embodiment of the invention.

FIG. 6 is a schematic cross-sectional view illustrating an organic electroluminescent device according to an embodiment of the invention.

FIG. 7 is a schematic cross-sectional view illustrating an organic electroluminescent device according to another embodiment of the invention.

FIG. 8 illustrates the correlation between a logarithmic current and a voltage in the organic electroluminescent devices according to an embodiment of the invention.

### DESCRIPTION OF EMBODIMENTS

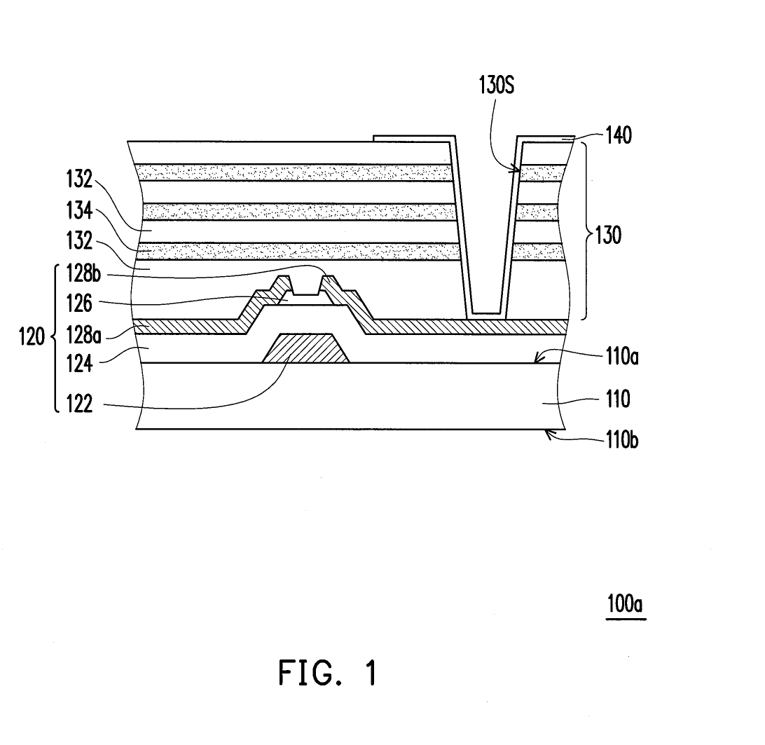

FIG. 1 is a schematic cross-sectional view illustrating a flexible active device array substrate 100a according to a first embodiment of the invention. With reference to FIG. 1, the flexible active device array substrate 100a includes a flexible substrate 110, an active device array layer 120, a barrier layer 130, and a plurality of pixel electrodes 140 according to the present embodiment. The active device array layer 120 is disposed on the flexible substrate 110. The barrier layer 130 covers the active device array layer 120. The barrier layer 130 includes a plurality of organic material layers 132 and a plurality of inorganic material layers 134. The organic material layers 132 and the inorganic material layers 134 are alternately stacked on the active device array layer 120. The pixel electrodes 140 are disposed on the barrier layer 130, and each of the pixel electrodes 140 is electrically connected to the active device array layer 120.

The flexible substrate 110 has an inner surface 110a and an outer surface 110b. For instance, the flexible substrate 110 is an organic substrate, a thin metal substrate, or an alloy substrate. In the present embodiment, the organic substrate taken for example may be a polyimide (PI) substrate, a polycarbonate substrate, a polyethylene terephthalate (PET) substrate, a poly(ethylene 2,6-napthalate) (PEN) substrate, a polypropylene substrate, a polyethylene substrate, a polystyrene substrate, or a substrate formed with the above polymer derivates.

The active device array layer 120 is disposed on the inner surface 110a of the flexible substrate 110. In the present embodiment, the active device array layer 120 is, for instance, a thin film transistor (TFT) array. The active device array layer 120 includes a gate 122, an insulation layer 124, a channel layer 126, a source 128a, and a drain 128b. The gate 122 is disposed on the inner surface 110a of the flexible substrate 110. The insulation layer 124 is disposed on the inner surface 110a of the flexible substrate 110 and covers the gate 122. The channel layer 126 is disposed on the insulation layer 124 and made of amorphous silicon, for instance. The source 128a and the drain 128b cover the insulation layer 124 and the channel layer 126. Besides, the source 128a and the drain 128b are separated from each other on the channel layer 126. However, the invention is not limited thereto, and the active device array layer 120 in other embodiments may be an organic TFT, an oxide TFT, a poly-silicon TFT, a micro-silicon TFT, or any other appropriate active device.

The barrier layer 130 covers the active device array layer 120 and includes a plurality of organic material layers 132 and a plurality of inorganic material layers 134, and the organic material layers 132 and the inorganic material layers 134 are alternately stacked on the active device array layer 120. A method of forming the organic material layers 132 may be a spin-coating method, a slit-coating method, or an inkjet printing method, and the organic material layers 132 are made of acrylate, for instance. Since the organic material layers 132 are not prone to be cracked after being bent, the organic material layers 132 are rather applicable to the flexible active device array substrate 100a. By contrast, a method of forming the inorganic material layers 134 may be a chemical vapor deposition (CVD) method, an atomic layer deposition method, a sputtering method, or any other appropriate thin film deposition method, for instance, and the inorganic material layers 134 are made of silicon oxide or silicon nitride, for instance. Since the material of the inorganic material layers 134 has a fine stacked structure, a water vapor transmission rate (WVTR) of the inorganic material layers 134 is rather low, so as to protect the active device array layer 120 from water vapor (humidity). As a whole, the barrier layer 130 formed by alternately stacking the organic material layers 132 and the inorganic material layers 134 not only has desirable flexibility but also has the WVTR substantially equal to or less than about 10⁻² g/m²·Day, preferably substantially equal to or less than about 10⁻⁶ g/m². Hence, the barrier layer 130 can further prevent waver vapor (humidity) intrusion.

In the present embodiment, a thickness of the organic material layers 132 is greater than about 0.2 μm, a thickness of the inorganic material layers 134 is greater than about 0.1 μm, and a thickness of the barrier layer 130 is greater than about 0.3 μm, for instance.

The pixel electrodes 140 are configured on the barrier layer 130. A material of the pixel electrodes 140 may be a transparent conductive material or a non-transparent conductive material, for instance. Here, the transparent conductive material may be metal oxide, and the non-transparent conductive material may be metal, for instance. Note that the barrier layer 130 described in the present embodiment may further have an opening 130S to expose the drain 128b of the active device array layer 120. The pixel electrodes 140 cover the barrier layer 130 and the drain 128b and are electrically connected to the active device array layer 120 through the opening 130S. To be more specific, the pixel electrodes 140 are electrically connected to the drain 128b of the active device array layer 120 through the opening 130S of the barrier layer 130.

Several embodiments are provided hereinafter to elaborate the flexible active device array substrates 100b, 100c, 100d, and 100e. It should be mentioned that the reference numbers and some of the descriptions in the previous embodiment are applicable in the following embodiments. Identical or similar components in the previous and following embodiments are denoted by identical reference numbers, and the same descriptions in the previous and following embodiments are not reiterated herein. Specifically, these components can be learned from the explanation in the previous embodiment, and thus no other descriptions are provided below.

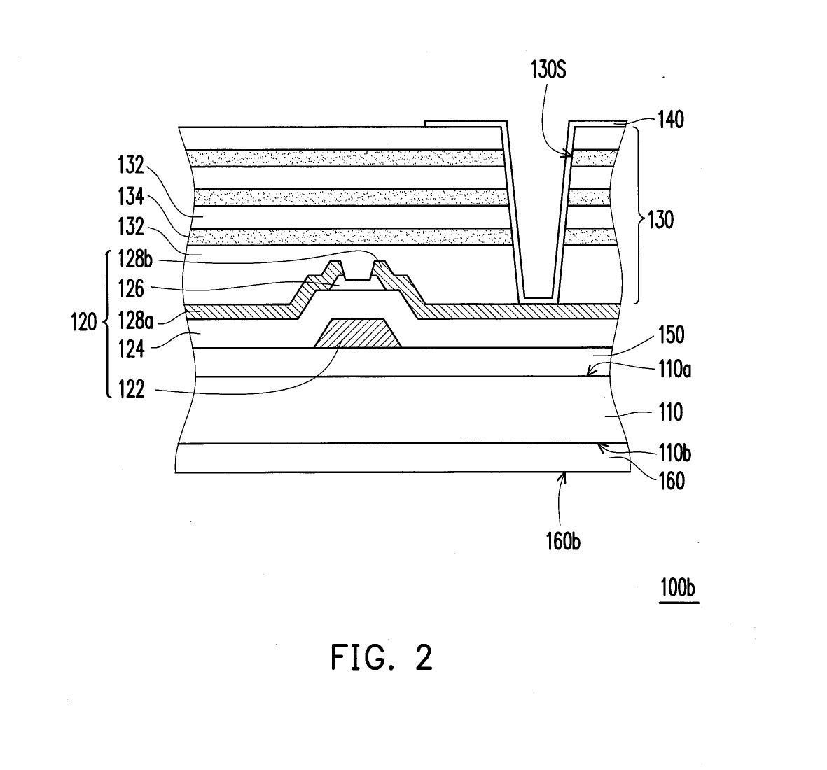

FIG. 2 is a schematic cross-sectional view illustrating a flexible active device array substrate 100b according to a second embodiment of the invention. With reference to FIG. 2, the flexible active device array substrate 100b of the present embodiment is similar to the flexible active device array substrate 100a of the first embodiment, while the difference therebetween rests in that the flexible active device array substrate 100b described herein further includes an inner barrier layer 150 and a first outer barrier layer 160. The inner barrier layer 150 is disposed on the inner surface 110a of the flexible substrate 110 and located between the flexible substrate 110 and the active device array layer 120. The first outer barrier layer 160 is disposed on the outer surface 110b of the flexible substrate 110 and has an outer surface 160b. Particularly, the inner barrier layer 150 and the first outer barrier layer 160 are respectively located on the inner surface 110a and the outer surface 110b of the flexible substrate 110. In other words, the flexible active device array substrate 100b have the inner barrier layer 150 and the first outer barrier layer 160 that are respectively located on two opposite sides of the flexible substrate 110. However, the invention is not limited thereto, and the flexible active device array substrate 100b in other embodiments (not shown) may merely have the inner barrier layer 150 or the first outer barrier layer 160 that is located on the inner surface 110a or the outer surface 110b of the flexible substrate 110.

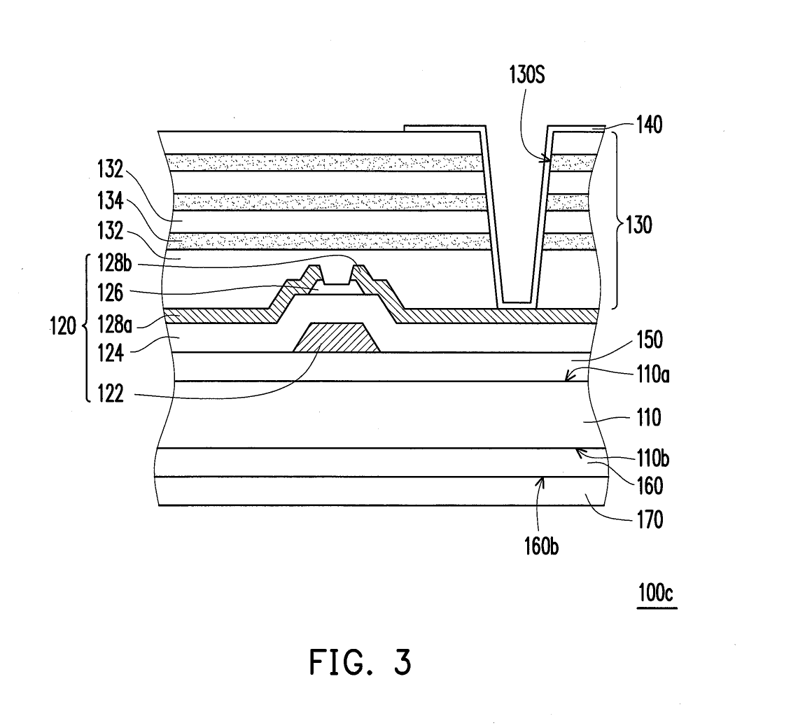

FIG. 3 is a schematic cross-sectional view illustrating a flexible active device array substrate 100c according to a third embodiment of the invention. With reference to FIG. 3, the flexible active device array substrate 100c of the present embodiment is similar to the flexible active device array substrate 100b of the second embodiment, while the difference therebetween rests in that the flexible active device array substrate 100c described herein further includes a second outer barrier layer 170. The second outer barrier layer 170 is disposed on the outer surface 160b of the first outer barrier layer 160. In particular, the first outer barrier layer 160 is located between the second outer barrier layer 170 and the flexible substrate 110.

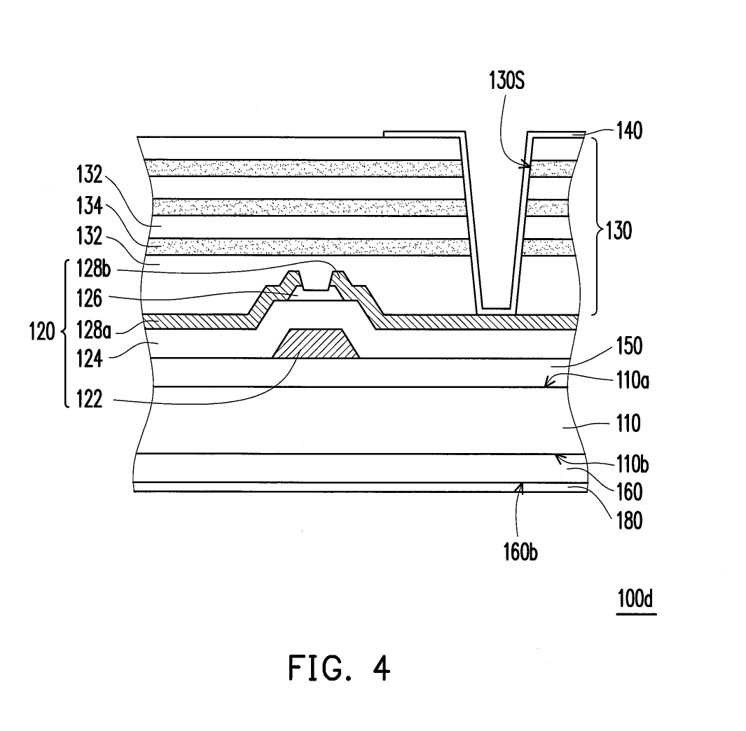

FIG. 4 is a schematic cross-sectional view illustrating a flexible active device array substrate 100d according to a fourth embodiment of the invention. With reference to FIG. 4, the flexible active device array substrate 100d of the present embodiment is similar to the flexible active device array substrate 100b of the second embodiment, while the difference therebetween rests in that the flexible active device array substrate 100d described herein further includes a de-bonding layer 180. The de-bonding layer 180 is disposed on the outer surface 160b of the first outer barrier layer 160. Specifically, the de-bonding layer 180 is adhered to the outer surface 160b of the first outer barrier layer 160, for instance.

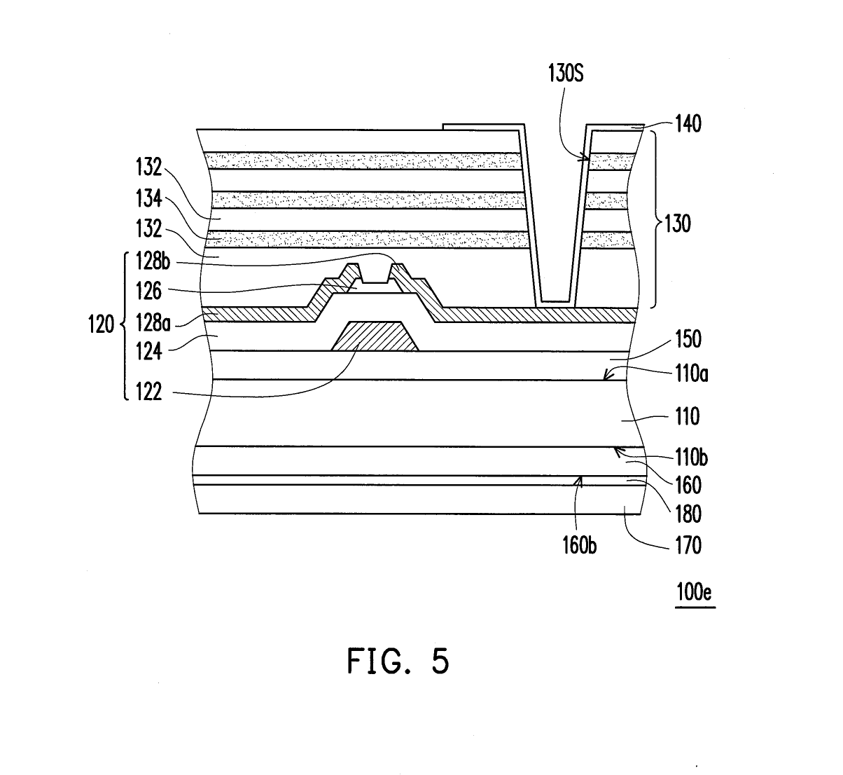

FIG. 5 is a schematic cross-sectional view illustrating a flexible active device array substrate 100e according to a fifth embodiment of the invention. With reference to FIG. 5, the flexible active device array substrate 100e of the present embodiment is similar to the flexible active device array substrate 100d of the fourth embodiment, while the difference therebetween rests in that the flexible active device array substrate 100e described herein further includes a second outer barrier layer 170. The second outer barrier layer 170 is disposed on the outer surface 160b of the first outer barrier layer 160, and the first outer barrier layer 160 is located between the second outer barrier layer 170 and the flexible substrate 110. Besides, the de-bonding layer 180 is adhered between the first outer barrier layer 160 and the second outer barrier layer 180, for instance.

It should be mentioned that the inner barrier layer 150, the first outer barrier layer 160, the second outer barrier layer 170, and the de-bonding layer 180 are all capable of preventing waver vapor (humidity) from entering the active device array layer 120 along a thickness direction of the flexible substrate 110. That is, the humidity could not enter the active device array layer 120 from the bottom of the flexible active device array substrate 100e. Therefore, the flexible active device array substrates 100b-100e described in the embodiments of the invention are impervious to waver vapor (humidity).

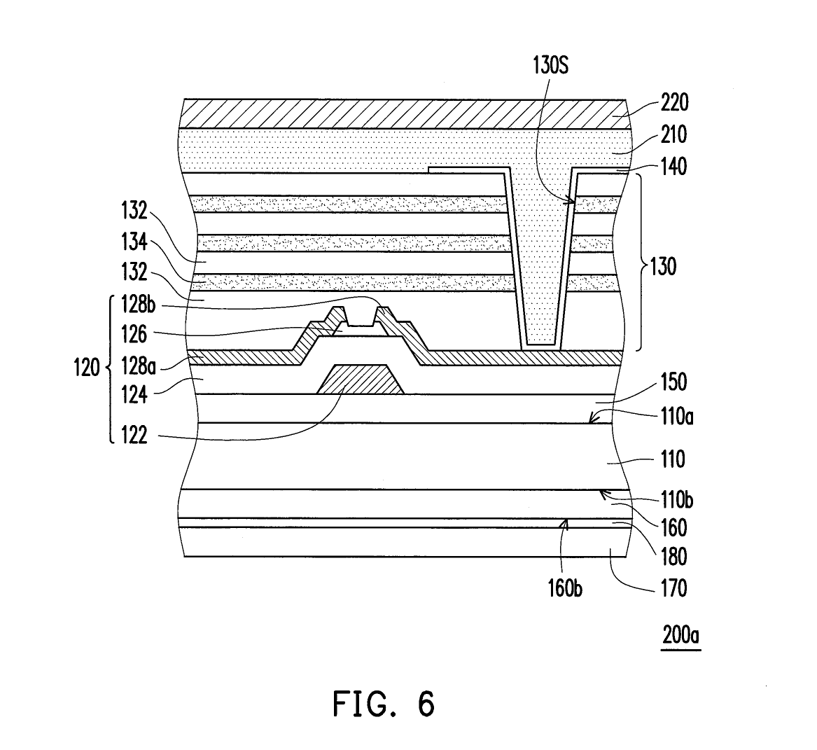

FIG. 6 is a schematic cross-sectional view illustrating an organic electroluminescent device 200a according to an embodiment of the invention. With reference to FIG. 6, the organic electroluminescent device 200a includes the flexible active device array substrate 100e, an organic electroluminescent layer 210, and an electrode layer 220. The flexible active device array substrate 100e depicted in FIG. 5 is exemplarily applied in the present embodiment; certainly, in other embodiments, the flexible active device array substrate may refer to the flexible active device array substrate 100a depicted in FIG. 1, the flexible active device array substrate 100b depicted in FIG. 2, the flexible active device array substrate 100c depicted in FIG. 3, or the flexible active device array substrate 100d depicted in FIG. 4, which should by no means be construed as a limitation to the invention.

The organic electroluminescent layer 210 is disposed on the flexible active device array substrate 100e. In the present embodiment, the organic electroluminescent layer 210 is electrically connected to the active device array layer 120 through the pixel electrodes 140. Here, the organic electroluminescent layer 210 may include a red organic light emitting pattern, a green organic light emitting pattern, a blue organic light emitting pattern, a light emitting pattern with other colors, or a combination of the aforesaid light emitting patterns. A method of forming the organic electroluminescent layer 210 may be an evaporation method, a coating method, a deposition method, or any other appropriate method, for instance.

The electrode layer 220 is disposed on the organic electroluminescent layer 210 and electrically insulated from the pixel electrodes 140. Here, the electrode layer 220 is transparent conductive substance, for instance. To be more specific, the pixel electrodes 140 in the flexible active device array substrate 100e are the cathodes, and the electrode layer 220 is the anode, for instance. With said configuration and the organic electroluminescent layer 210, the organic electroluminescent device 200a described in the present embodiment can be formed.

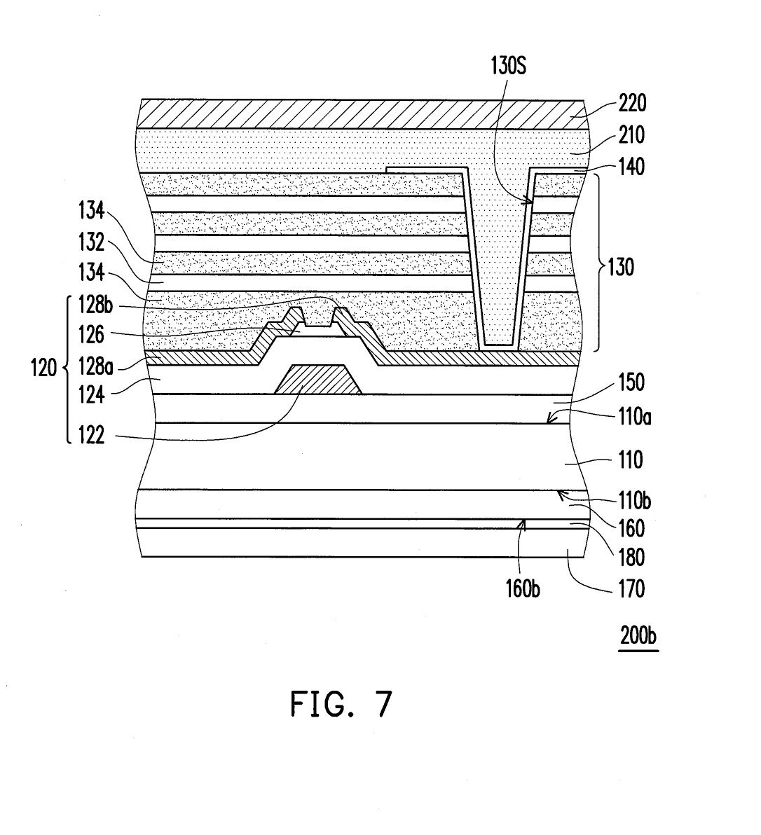

In the organic electroluminescent device 200a, a bottommost layer of the barrier layer 130 which is in contact with the active device array layer 120 is preferably an organic material layer, for instance. However, the invention is not limited thereto. FIG. 7 is a schematic cross-sectional view illustrating an organic electroluminescent device 200b according to another embodiment of the invention. With reference to FIG. 7, the structure of the organic electroluminescent device 200b herein is similar to the structure of the organic electroluminescent device 200a in the previous embodiment, while one of the differences therebetween lies in that the bottommost layer of the barrier layer 130 which is in contact with the active device array layer 120 is an inorganic material layer.

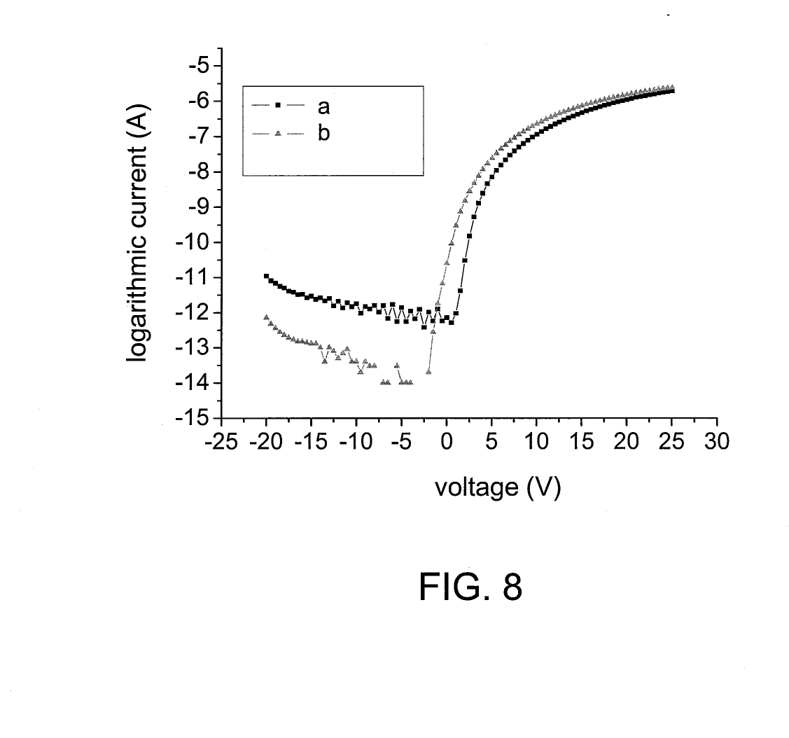

FIG. 8 illustrates the correlation between a logarithmic current and a voltage in the organic electroluminescent devices 200a and 200b according to an embodiment of the invention. With reference to FIG. 8, the curve a indicates the correlation between a logarithmic current and a voltage in the organic electroluminescent device 200a, and the curve b indicates the correlation between a logarithmic current and a voltage in the organic electroluminescent device 200b. It can be observed from the curves a and b that both the organic electroluminescent devices 200a and 200b have favorable device properties.

In light of the foregoing, the flexible active device array substrate described in the embodiments of the invention is equipped with the barrier layer that is stacked by the organic material layers and the inorganic material layers alternately. Therefore, the flexible active device array substrate described in the embodiments of the invention has flexibility and is less vulnerable to waver vapor (humidity) intrusion. Moreover, the flexible active device array substrate herein further includes the inner barrier layer, the first outer barrier layer, the second outer barrier layer, and the de-bonding layer, thus achieving the function of preventing waver vapor (humidity) from entering the active device array layer along a direction of the flexible substrate. As such, the flexible active device array substrate described in the embodiments of the invention is impervious to waver vapor (humidity) and can have desirable reliability.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A flexible active device array substrate, comprising:
a flexible substrate; and
an active device array layer disposed on the flexible substrate;
a barrier layer covering the active device array layer and comprising:
a plurality of organic material layers; and
a plurality of inorganic material layers, wherein the organic material layers and the inorganic material layers are alternately stacked on the active device array layer; and
a plurality of pixel electrodes disposed on the barrier layer, each of the pixel electrodes being electrically connected to the active device array layer.

2. The flexible active device array substrate as recited in claim 1, wherein a water vapor transmission rate of the barrier layer is substantially equal to or less than 10⁻² g/m²·Day.

3. The flexible active device array substrate as recited in claim 1, wherein a bottommost organic material layer of the organic material layers is in contact with the active device array layer.

4. The flexible active device array substrate as recited in claim 1, wherein a bottommost inorganic material layer of the inorganic material layers is in contact with the active device array layer.

5. The flexible active device array substrate as recited in claim 1, further comprising an inner barrier layer disposed between the flexible substrate and the active device array layer.

6. The flexible active device array substrate as recited in claim 5, further comprising a first outer barrier layer disposed on an outer surface of the flexible substrate, wherein the inner barrier layer and the first outer barrier layer are respectively located at two opposite sides of the flexible substrate.

7. The flexible active device array substrate as recited in claim 6, further comprising a second outer barrier layer disposed on an outer surface of the first outer barrier layer, wherein the first outer barrier layer is located between the second outer barrier layer and the flexible substrate.

8. The flexible active device array substrate as recited in claim 6 further comprising:
a second outer barrier layer disposed on an outer surface of the first outer barrier layer, wherein the first outer barrier layer is located between the second outer barrier layer and the flexible substrate; and
a de-bonding layer adhered between the first outer barrier layer and the second outer barrier layer.

9. The flexible active device array substrate as recited in claim 6, further comprising a de-bonding layer disposed on an outer surface of the first outer barrier layer.

10. An organic electroluminescent device comprising:
the flexible active device array substrate as recited in claim 1;
an organic electroluminescent layer disposed on the flexible active device array substrate; and
an electrode layer disposed on the organic electroluminescent layer, wherein the electrode layer is electrically insulated from the pixel electrodes.

11. The organic electroluminescent device as recited in claim 10, wherein a water vapor transmission rate of the barrier layer is substantially equal to or less than 10⁻² g/m²·Day.

12. The organic electroluminescent device as recited in claim 10, wherein a bottommost organic material layer of the organic material layers is in contact with the active device array layer.

13. The organic electroluminescent device as recited in claim 10, wherein a bottommost inorganic material layer of the inorganic material layers is in contact with the active device array layer.

14. The organic electroluminescent device as recited in claim 10, wherein the flexible active device array substrate further comprises an inner barrier layer disposed between the flexible substrate and the active device array layer.

15. The organic electroluminescent device as recited in claim 14, wherein the flexible active device array substrate further comprises a first outer barrier layer disposed on an outer surface of the flexible substrate, and the inner barrier layer and the first outer barrier layer are respectively located at two opposite sides of the flexible substrate.

16. The organic electroluminescent device as recited in claim 15, wherein the flexible active device array substrate further comprises a second outer barrier layer disposed on an outer surface of the first outer barrier layer, and the first outer barrier layer is located between the second outer barrier layer and the flexible substrate.

17. The organic electroluminescent device as recited in claim 15, wherein the flexible active device array substrate further comprises:
a second outer barrier layer disposed on an outer surface of the first outer barrier layer, wherein the first outer barrier layer is located between the second outer barrier layer and the flexible substrate; and
a de-bonding layer adhered between the first outer barrier layer and the second outer barrier layer.

18. The organic electroluminescent device as recited in claim 15, wherein the flexible active device array substrate further comprises a de-bonding layer disposed on an outer surface of the first outer barrier layer.
